(19) United States
(12) Patent Application Publication
(10) Pub. No.: US 2025/0212452 A1
(43) Pub. Date: Jun. 26, 2025

(54) FINFET DEVICE AND METHOD FOR MANUFACTURING SAME

(71) Applicant: Microchip Technology Incorporated, Chandler, AZ (US)

(72) Inventors: Shesh Mani Pandey, Gilbert, AZ (US); Bruce Odekirk, Portland, OR (US); Randy L. Yach, Phoenix, AZ (US)

(73) Assignee: Microchip Technology Incorporated, Chandler, AZ (US)

(21) Appl. No.: 18/739,805

(22) Filed: Jun. 11, 2024

Related U.S. Application Data
(60) Provisional application No. 63/612,837, filed on Dec. 20, 2023.

(51) Int. Cl. H01L 29/78; H01L 29/10; H01L 29/16; H01L 29/20; H01L 29/66

(52) U.S. Cl. CPC H10D 30/63; H10D 12/031; H10D 30/01; H10D 30/021; H10D 30/025; H10D 62/292; H10D 62/8303; H10D 62/8325; H10D 62/8503

(57) ABSTRACT

A FinFET device that may include a substrate. A drain layer on a first side of the substrate. A drift layer on a second side of the substrate. The drift layer having a fin-shaped portion and a recessed portion. A doped-well layer over the fin-shaped portion of the drift layer. An insulating layer over the doped-well layer and over the recessed portion of the drift layer. A gate electrode over the insulating layer.

### CROSS-REFERENCE TO RELATED APPLICATION

The present application claims priority to U.S. Provisional Patent Application No. 63/612,837, filed on Dec. 20, 2023, the contents of which are hereby incorporated by reference in their entirety.

### TECHNICAL FIELD

The present disclosure relates to semiconductor devices, and more specifically to finFETs and methods for manufacturing same to increase the current density capacity the finFET.

### SUMMARY

According to an aspect of one or more examples, there is provided a method for fabricating a FinFET device that may include providing a substrate, forming a drain layer on a first side of the substrate, forming a drift layer on a second side of the substrate, the drift layer having a fin-shaped portion and a recessed portion, forming a doped-well layer over the fin-shaped portion of the drift layer, forming an insulating layer over the doped-well layer and over the recessed portion of the drift layer, and forming a gate electrode over the insulating layer. The substrate may comprise bulk gallium nitride, diamond, silicon carbide, sapphire, aluminum nitride, or silicon. The substrate may comprise a first type dopant. The drain layer may comprise a first concentration of the first type dopant. The drift layer may comprise a second concentration of the first type dopant. The first concentration of the first type dopant may be greater than the second concentration of the first type dopant. The doped-well layer may comprise a third concentration of a second type dopant. The insulating layer may comprise polysilicon, silicon dioxide or a mixture of polysilicon and silicon dioxide.

According to an aspect of one or more examples, there is provided a FinFET device that may include a substrate, a drain layer on a first side of the substrate, a drift layer on a second side of the substrate, the drift layer having a fin-shaped portion and a recessed portion, a doped-well layer over the fin-shaped portion of the drift layer, an insulating layer over the doped-well layer and over the recessed portion of the drift layer, and a gate electrode over the insulating layer. The substrate may comprise bulk gallium nitride, diamond, silicon carbide, sapphire, aluminum nitride, or silicon. The substrate may comprise a first type dopant. The drain layer may comprise a first concentration of the first type dopant. The drift layer may comprise a second concentration of the first type dopant. The first concentration of the first type dopant may be greater than the second concentration of the first type dopant. The doped-well layer may comprise a third concentration of a second type dopant. The insulating layer may comprise polysilicon, silicon dioxide or a mixture of polysilicon and silicon dioxide.

### BRIEF DESCRIPTION OF DRAWINGS

FIG. 1A is a cross sectional side view of a FinFET device according to one or more examples;

FIG. 1B is a cross sectional front view of a FinFET device without the gate electrode according to one or more examples;

FIG. 1C is a cross sectional front view of a FinFET device according to one or more examples;

FIG. 2A is cross sectional side view of some of the steps in a method of manufacturing a FinFET device according to one or more examples;

FIG. 2B is cross sectional side view of some of the steps in a method of manufacturing a FinFET device according to one or more examples;

FIG. 2C is cross sectional side view some of the steps in a method of manufacturing a FinFET device according to one or more examples;

FIG. 2D a cross sectional side view of some of the steps in a method of manufacturing a FinFET device according to one or more examples;

FIG. 2E a cross sectional side view of some of the steps in a method of manufacturing a FinFET device according to one or more examples;

FIG. 2F is a cross sectional front view of some of the steps in a method of manufacturing a FinFET device according to one or more examples; and

FIG. 2G is a cross sectional front view of some of the steps in a method of manufacturing a FinFET device according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein. Various examples are provided below based on a first dopant type (n-type substrate) with a doped-well with a second dopant type (p-well), it being understood that a p-type substrate, being the first dopant type, with an n-well, being the second dopant type, may be utilized with the same device structure. Thus, in one example, an n-type may be considered a first type, and a p-type may be considered a second type. In another example, a p-type may be considered a first type, and an n-type may be considered a second type.

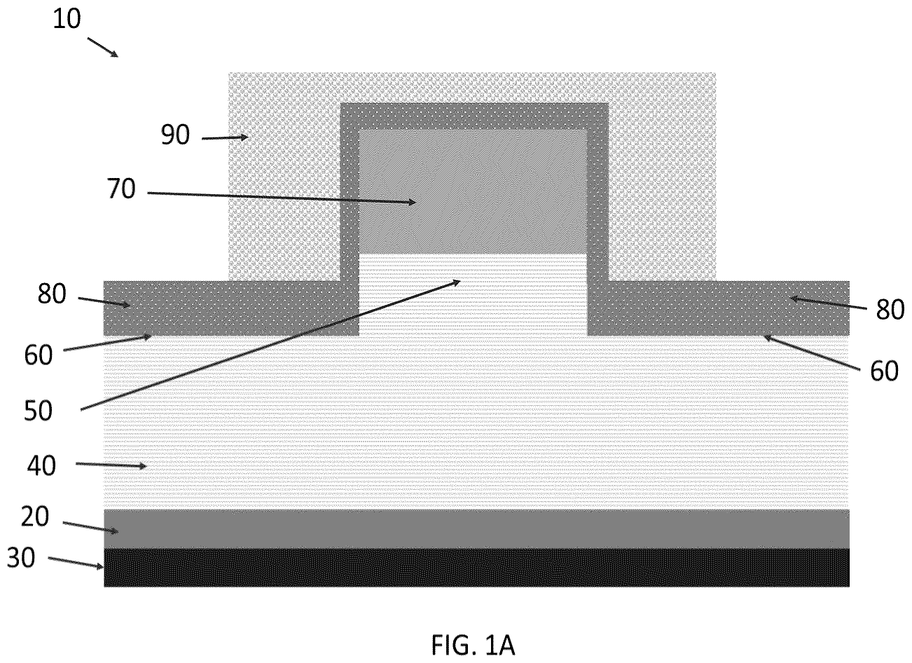

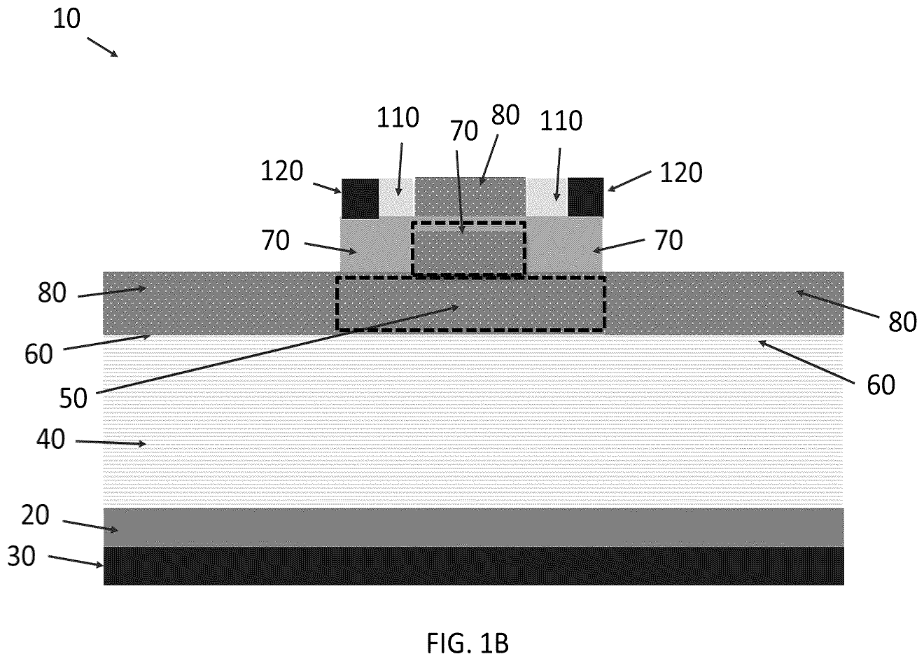

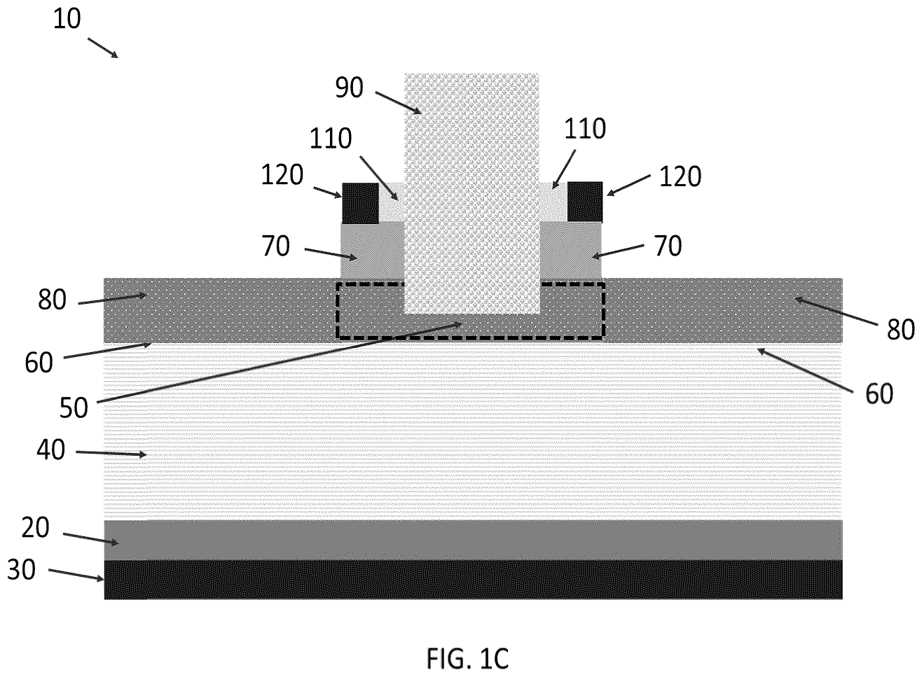

FIG. 1A is a cross sectional side view of a FinFET device 10 according to one or more examples. As shown in FIG. 1, the FinFET device 10 may have a substrate 20 that may have a first dopant type. The substrate 20 may comprise bulk gallium nitride, diamond, silicon carbide, aluminum nitride, or silicon. The substrate 20 may be doped so as to have a resistivity of less than 25 milliohm-cm. A drain layer 30 may have a first concentration of the first type dopant and may be formed on a first side of the substrate 20. The drain layer 30 may comprise bulk gallium nitride, diamond, silicon carbide, aluminum nitride, or silicon. A drift layer 40 may have a second concentration of the first type dopant and may be formed on a second side of the substrate 20, the second side opposite the first side. The drift layer 40 may comprise bulk gallium nitride, diamond, silicon carbide, aluminum nitride, or silicon. The drift layer 40 and the drain layer 30 may be any combination of bulk gallium nitride, diamond, silicon carbide, aluminum nitride, or silicon provided there is no barrier to current flow created by the heterojunction between the drift layer 40 and the drain layer 30.

The first concentration of the first type dopant in the drain layer 30 may be greater than the second concentration of the first type dopant in the drift layer 40. The drift layer 40 may have a fin-shaped portion 50 and recessed portions 60. A doped-well layer 70 may be formed over the fin-shaped portion 50 of the drift layer 40. The doped-well layer 70 may have a third concentration of a second type dopant. An insulating layer 80 such as polysilicon, silicon dioxide or a mixture of polysilicon and dioxide may be formed over the doped-well layer 70 and over the recessed portions 60 of the drift layer 40. A gate electrode 90 may be formed over the insulating layer 80.

FIG. 1B is a cross sectional front view of a FinFET device 10 of FIG. 1A without the gate electrode 90 according to one or more examples. As shown in FIG. 1B, the FinFET device 10 may have a substrate 20 that may have a first dopant type. The substrate 20 may comprise bulk gallium nitride, diamond, silicon carbide, aluminum nitride, or silicon. A drain layer 30 may have a first concentration of the first type dopant and may be formed on a first side of the substrate 20. The drain layer 30 may comprise bulk gallium nitride, diamond, silicon carbide, aluminum nitride, or silicon. A drift layer 40 may have a second concentration of the first type dopant and may be formed on a second side of the substrate 20, the second side opposite the first side. The drift layer 40 may comprise bulk gallium nitride, diamond, silicon carbide, aluminum nitride, or silicon. The first concentration of the first type dopant in the drain layer 30 may be greater than the second concentration of the first type dopant in the drift layer 40. The drift layer 40 may have a fin-shaped portion 50 and recessed portions 60. A doped-well layer 70 may be formed over the fin-shaped portion 50 of the drift layer 40. The doped-well layer 70 may have a third concentration of a second type dopant. An insulating layer 80 such as polysilicon, silicon dioxide or a mixture of polysilicon and dioxide may be formed over the doped-well layer 70 and the recessed portions 60 of the drift layer 40. A source 110 may be formed over the doped-well layer 70. A body 120 may be formed over the doped-well layer 70.

FIG. 1C is a cross sectional front view of a FinFET device 10 of FIG. 1A according to one or more examples. As shown in FIG. 1C, the FinFET device 10 may have a substrate 20 that may have a first dopant type. The substrate 20 may comprise bulk gallium nitride, diamond, silicon carbide, aluminum nitride, or silicon. A drain layer 30 may have a first concentration of the first type dopant and may be formed on a first side of the substrate 20. The drain layer 30 may comprise bulk gallium nitride, diamond, silicon carbide, aluminum nitride, or silicon. A drift layer 40 may have a second concentration of the first type dopant and may be formed on a second side of the substrate 20, the second side opposite the first side. The drift layer 40 may comprise bulk gallium nitride, diamond, silicon carbide, aluminum nitride, or silicon. The first concentration of the first type dopant in the drain layer 30 may be greater than the second concentration of the first type dopant in the drift layer 40. The drift layer 40 may have a fin-shaped portion 50 and recessed portions 60. A doped-well layer 70 may be formed over the fin-shaped portion 50 of the drift layer 40. The doped-well layer 70 may have a third concentration of a second type dopant. An insulating layer 80 such as polysilicon, silicon dioxide or a mixture of polysilicon and dioxide may be formed over the doped-well layer 70 and the recessed portions 60 of the drift layer 40. A source 110 may be formed over the doped-well layer 70. A body 120 may be formed over the doped-well layer 70. A gate electrode 90 may be formed over the insulating layer 80.

In the example FinFET device 10 of FIGS. 1A-1C, a channel for flow of charge carriers may be created from the source 110 through the doped-well layer 70 though the drift layer 40 to the drain layer 30.

In the example FinFET device 10 of FIGS. 1A-1C, the first type dopant may be an n-type dopant with the second type dopant being a p-type dopant. Alternatively, the first type dopant may be a p-type dopant with the second type dopant being an n-type dopant.

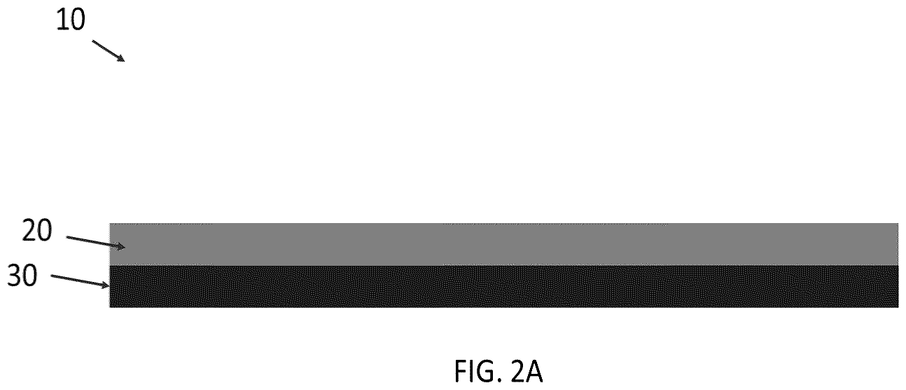

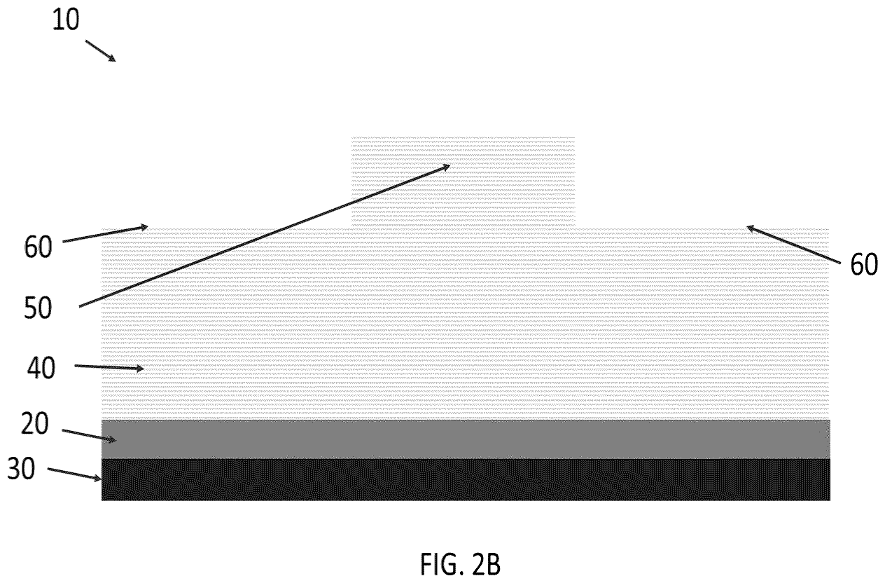

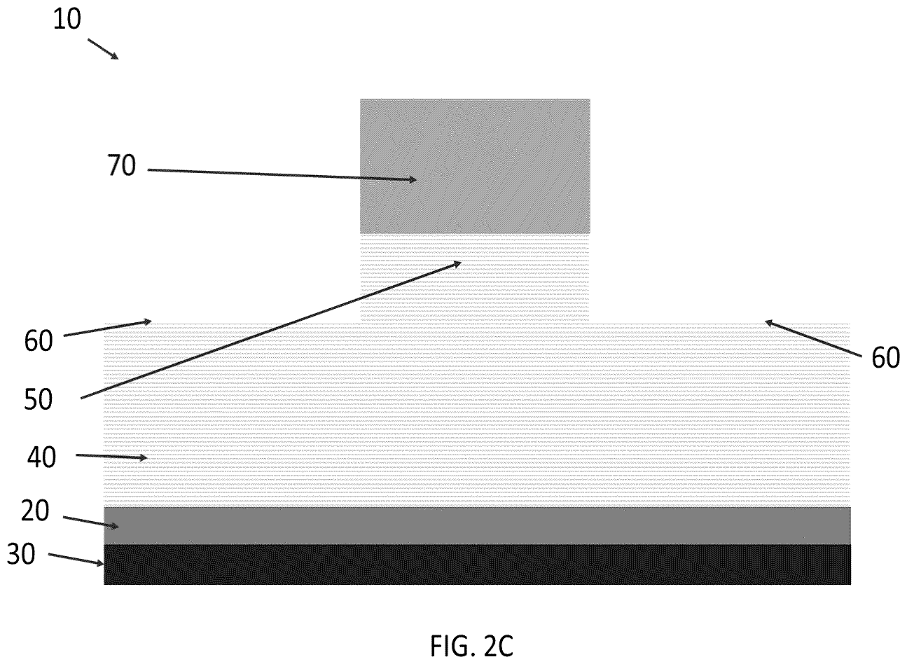

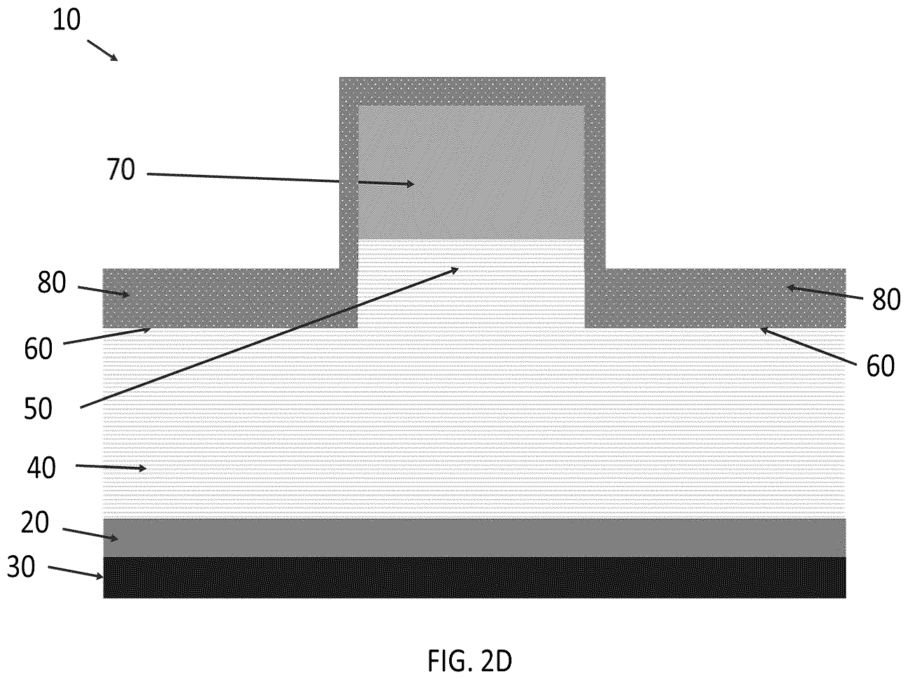

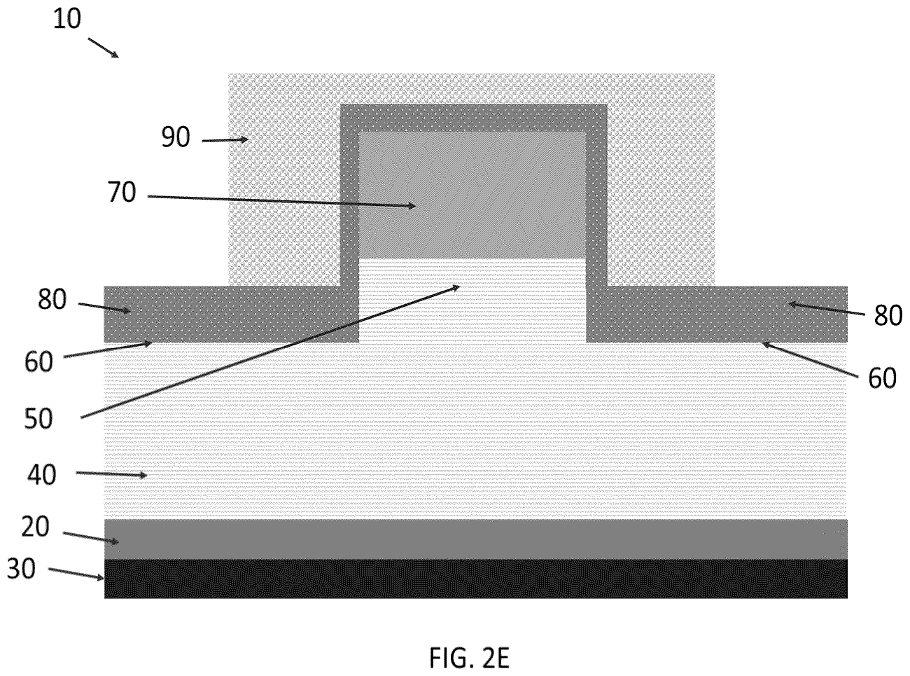

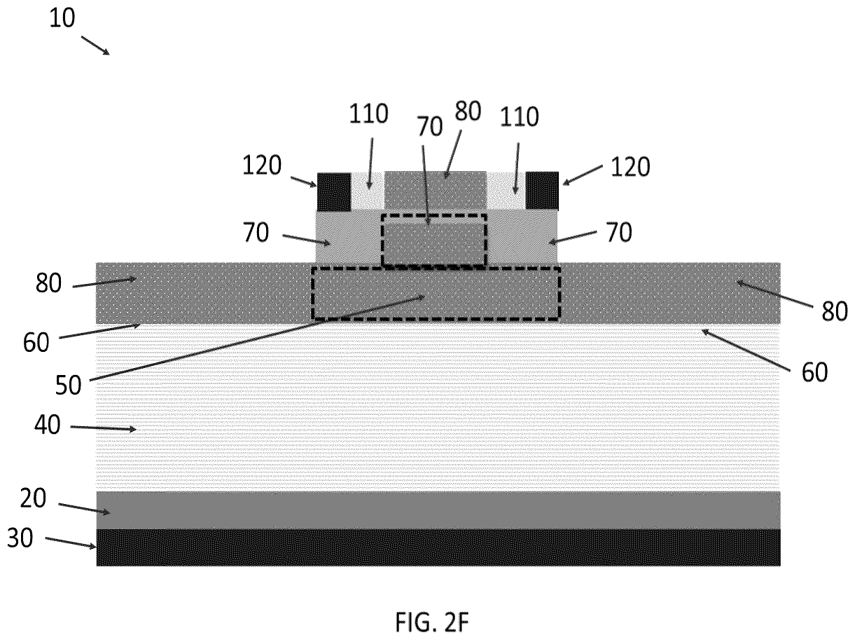

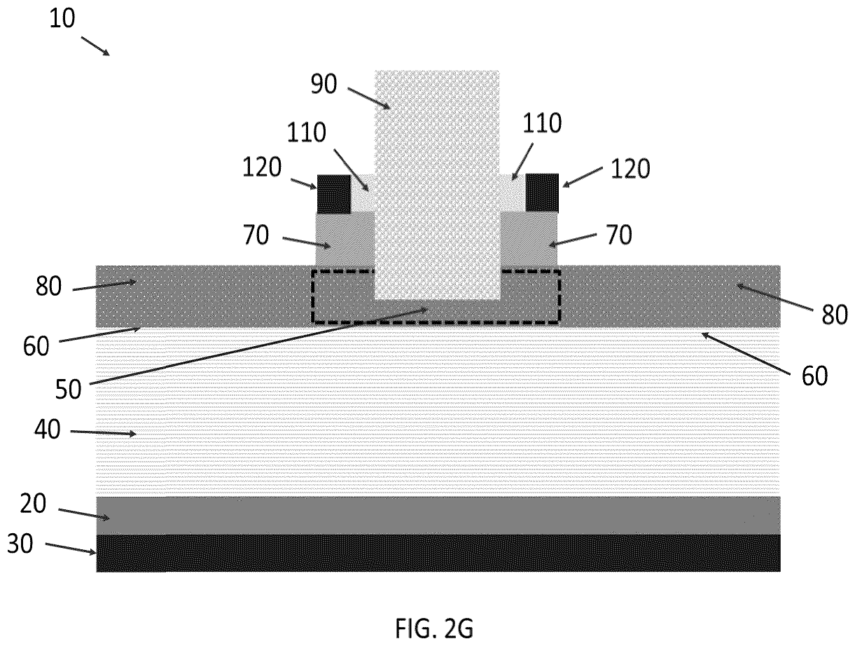

FIGS. 2A-2F show a method of manufacturing a FinFET device according to one or more examples. Although the example method shown in FIGS. 2A-2F include steps shown in a particular order, the steps may be performed in a different order, and may include additional steps that are not explicitly shown. In addition, each step presented herein may have multi-steps necessary to carry out the stated step that are not explicitly shown or stated herein.

FIG. 2A is a cross sectional side view of some of the steps in a method of manufacturing a FinFET device 10 according to one or more examples. In FIG. 2A, the example method may include forming a drain layer 30 that may have a first concentration of a first type dopant that may be on a first side of a substrate 20. The substrate 20 may have a first dopant type. The substrate 20 may comprise bulk gallium nitride, diamond, silicon carbide, aluminum nitride, or silicon. The drain layer 30 may comprise bulk gallium nitride, diamond, silicon carbide, aluminum nitride, or silicon.

FIG. 2B is a cross sectional side view of some of the steps in a method of manufacturing a FinFET device 10 according to one or more examples. In FIG. 2B, the example method may include forming a drift layer 40 on a second side of the substrate 20, the second side opposite the first side. The drift layer 40 may comprise bulk gallium nitride, diamond, silicon carbide, aluminum nitride, or silicon. The drift layer 40 and the drain layer 30 may be any combination of bulk gallium nitride, diamond, silicon carbide, aluminum nitride, or silicon provided there is no barrier to current flow created by the heterojunction between the drift layer 40 and the drain layer 30. The drift layer 40 may be formed with a fin-shaped portion 50 and recessed portions 60. The drift layer 40 may have a second concentration of the first type dopant. The first concentration of the first type dopant in the drain layer 30 may be greater than the second concentration of the first type dopant in the drift layer 40.

FIG. 2C is a cross sectional side view of some of the steps in a method of manufacturing a FinFET device according to one or more examples. In FIG. 2C, the example method may include forming a doped-well layer 70 over the fin-shaped portion 50 of the drift layer 40. The doped-well layer 70 may have a third concentration of a second type dopant.

FIG. 2D is a cross sectional side view of some of the steps in a method of manufacturing a FinFET device according to one or more examples. In FIG. 2D, the example method may include forming an insulating layer 80 such as polysilicon, silicon dioxide or a mixture of polysilicon and dioxide over the doped-well layer 70 and over the recessed portions 60 of the drift layer 40.

FIG. 2E is a cross sectional side view of some of the steps in a method of manufacturing a FinFET device according to one or more examples. In FIG. 2E, the example method may include forming a gate electrode 90 over the insulating layer 80.

FIG. 2F is a cross sectional front view of some of the steps in a method of manufacturing a FinFET device according to one or more examples. FIG. 2F is a cross sectional front view of a FinFET device 10 of FIG. 2E without the gate electrode 90 according to one or more examples. As shown in FIG. 2F, the FinFET device 10 may have a substrate 20 that may have a first dopant type. The substrate 20 may comprise bulk gallium nitride, diamond, silicon carbide, aluminum nitride, or silicon. A drain layer 30 may have a first concentration of the first type dopant and may be formed on a first side of the substrate 20. The drain layer 30 may comprise bulk gallium nitride, diamond, silicon carbide, aluminum nitride, or silicon. A drift layer 40 may have a second concentration of the first type dopant and may be formed on a second side of the substrate 20, the second side opposite the first side. The drift layer 40 may comprise bulk gallium nitride, diamond, silicon carbide, aluminum nitride, or silicon. The first concentration of the first type dopant in the drain layer 30 may be greater than the second concentration of the first type dopant in the drift layer 40. The drift layer 40 may have a fin-shaped portion 50 and recessed portions 60. A doped-well layer 70 may be formed over the fin-shaped portion 50 of the drift layer 40. The doped-well layer 70 may have a third concentration of a second type dopant. An insulating layer 80 such as polysilicon, silicon dioxide or a mixture of polysilicon and dioxide may be formed over the doped-well layer 70 and the recessed portions 60 of the drift layer 40. A source 110 may be formed over the doped-well layer 70. A body 120 may be formed over the doped-well layer 70.

FIG. 2G is a cross sectional front view of some of the steps in a method of manufacturing a FinFET device according to one or more examples. As shown in FIG. 2G, the FinFET device 10 may have a substrate 20 that may have a first dopant type. The substrate 20 may comprise bulk gallium nitride, diamond, silicon carbide, aluminum nitride, or silicon. A drain layer 30 may have a first concentration of the first type dopant and may be formed on a first side of the substrate 20. The drain layer 30 may comprise bulk gallium nitride, diamond, silicon carbide, aluminum nitride, or silicon. A drift layer 40 may have a second concentration of the first type dopant and may be formed on a second side of the substrate 20, the second side opposite the first side. The drift layer 40 may comprise bulk gallium nitride, diamond, silicon carbide, aluminum nitride, or silicon. The first concentration of the first type dopant in the drain layer 30 may be greater than the second concentration of the first type dopant in the drift layer 40. The drift layer 40 may have a fin-shaped portion 50 and recessed portions 60. A doped-well layer 70 may be formed over the fin-shaped portion 50 of the drift layer 40. The doped-well layer 70 may have a third concentration of a second type dopant. An insulating layer 80 such as polysilicon, silicon dioxide or a mixture of polysilicon and dioxide may be formed over the doped-well layer 70 and the recessed portions 60 of the drift layer 40. A source 110 may be formed over the doped-well layer 70. A body 120 may be formed over the doped-well layer 70. A gate electrode 90 may be formed over the insulating layer 80.

In the example FinFET device 10 of FIGS. 2A-2G, a channel for flow of charge carriers may be created from the source 110 through the doped-well layer 70 though the drift layer 40 to the drain layer 30.

In the example FinFET device 10 of FIGS. 2A-2G, the first type dopant may be an n-type dopant with the second type dopant being a p-type dopant. Alternatively, the first type dopant may be a p-type dopant with the second type dopant being an n-type dopant.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A method for fabricating a FinFET device, comprising:
providing a substrate;
forming a drain layer on a first side of the substrate;
forming a drift layer on a second side of the substrate, the drift layer having a fin-shaped portion and a recessed portion;
forming a doped-well layer over the fin-shaped portion of the drift layer;
forming an insulating layer over the doped-well layer and over the recessed portion of the drift layer; and
forming a gate electrode over the insulating layer.

2. The method for fabricating a FinFET according to claim 1, wherein the substrate comprises bulk gallium nitride, diamond, silicon carbide, aluminum nitride, or silicon.

3. The method for fabricating a FinFET according to claim 2, wherein the substrate comprises a first type dopant so as to have a resistivity of less than 25 milliohm-cm.

4. The method for fabricating a FinFET according to claim 3, wherein the drain layer comprises bulk gallium nitride, diamond, silicon carbide, aluminum nitride, or silicon.

5. The method for fabricating a FinFET according to claim 4, wherein the drain layer comprises a first concentration of the first type dopant.

6. The method for fabricating a FinFET according to claim 5, wherein the drift layer comprises bulk gallium nitride, diamond, silicon carbide, aluminum nitride, or silicon.

7. The method for fabricating a FinFET according to claim 6, wherein the drift layer comprises a second concentration of the first type dopant, the second concentration different from the first concentration.

8. The method for fabricating a FinFET according to claim 7, wherein the first concentration of the first type dopant is greater than the second concentration of the first type dopant.

9. The method for fabricating a FinFET according to claim 8, wherein the doped-well layer comprises a third concentration of a second type dopant.

10. The method for fabricating a FinFET according to claim 1, wherein the insulating layer comprises polysilicon, silicon dioxide or a mixture of polysilicon and silicon dioxide.

11. A FinFET device, comprising:
a substrate;
a drain layer on a first side of the substrate;
a drift layer on a second side of the substrate, the drift layer having a fin-shaped portion and a recessed portion;
a doped-well layer over the fin-shaped portion of the drift layer;
an insulating layer over the doped-well layer and over the recessed portion of the drift layer; and
a gate electrode over the insulating layer.

12. The FinFET device according to claim 11, wherein the substrate comprises bulk gallium nitride, diamond, silicon carbide, aluminum nitride, or silicon.

13. The FinFET device according to claim 12, wherein the substrate comprises a first type dopant so as to have a resistivity of less than 25 milliohm-cm.

14. The FinFET device according to claim 13, wherein the drain layer comprises bulk gallium nitride, diamond, silicon carbide, aluminum nitride, or silicon.

15. The FinFET device according to claim 14, wherein the drain layer comprises a first concentration of the first type dopant.

16. The FinFET device according to claim 15, wherein the drift layer comprises bulk gallium nitride, diamond, silicon carbide, aluminum nitride, or silicon.

17. The FinFET device according to claim 16, wherein the drift layer comprises a second concentration of the first type dopant, the second concentration different from the first concentration.

18. The FinFET device according to claim 17, wherein the first concentration of the first type dopant is greater than the second concentration of the first type dopant.

19. The FinFET device according to claim 18, wherein the doped-well layer comprises a third concentration of a second type dopant.

20. The FinFET device according to claim 11, wherein the insulating layer comprises polysilicon, silicon dioxide or a mixture of polysilicon and silicon dioxide.
